(19) United States
(12) Patent Application Publication
(10) Pub. No.: US 2021/0034164 A1
(43) Pub. Date: Feb. 4, 2021

(54) INPUT DEVICE AND ELECTRONIC APPARATUS

(71) Applicants: Hefei Xinsheng Optoelectronics Technology Co., Ltd, Hefei (CN); BOE Technology Group Co., Ltd., Beijing (CN)

(72) Inventors: Le LI, Beijing (CN); Baoran LI, Beijing (CN); Wenjin FAN, Beijing (CN); Chuanwen ZHANG, Beijing (CN)

(21) Appl. No.: 16/935,482

(22) Filed: Jul. 22, 2020

(30) Foreign Application Priority Data
Aug. 1, 2019 (CN) 201910708204.3

(51) Int. Cl. G06F 3/02; G06F 1/16

(52) U.S. Cl. CPC G06F 3/0202; G06F 1/1662; G06F 1/1626

(57) ABSTRACT

An input device and an electronic apparatus are provided. The input device includes an input region and a signal processing circuit. The input region includes a first press sensing optical fiber, a second press sensing optical fiber and a key region including a press layer. The first press sensing optical fiber is on a side of the press layer opposite to a user operation side and extends in a first direction. The second press sensing optical fiber is on a side of the first press sensing optical fiber distal to the press layer and extends in a second direction intersecting the first direction. The signal processing circuit is configured to transmit input optical signals to/receive output optical signals from the first and second press sensing optical fibers, and determine press information of the key region according to the output optical signals.

### CROSS-REFERENCE TO RELATED APPLICATION

The present application claims priority from Chinese patent application No. 201910708204.3 filed on Aug. 1, 2019, the content of which is incorporated herein in its entirety by reference.

### TECHNICAL FIELD

The present disclosure relates to the field of information transmission technologies, in particular to an input device and an electronic apparatus (or electronic terminal).

### BACKGROUND

Information is input to an electronic terminal (for example, a computer, a mobile phone, and the like) by using an input device. The input device may be a keyboard. Conventional keyboards include mechanical keyboards and capacitive keyboards. Each mechanical keyboard has a large thickness, and a high failure rate due to the easy breaking of a copper sheet used therein as a touch switch. Each capacitive keyboard does not have the disadvantages of the mechanical keyboard, but has a complex manufacturing process.

### SUMMARY

Embodiments of the present disclosure provide an input device and an electronic apparatus.

A first aspect of the present disclosure provides an input device for inputting information to an electronic terminal, including an input region and a signal processing circuit,

wherein the input region includes at least one sub-input region, each of the at least one sub-input region includes at least one first press sensing optical fiber, at least one second press sensing optical fiber and at least one key region;

each of the at least one key region includes a press layer;

the at least one first press sensing optical fiber is on a side of the press layer opposite to a user operation side of the press layer and extends in a first direction;

the at least one second press sensing optical fiber is on a side of the at least one first press sensing optical fiber distal to the press layer and extends in a second direction intersecting the first direction;

the signal processing circuit is coupled to the at least one first press sensing optical fiber and the at least one second press sensing optical fiber, and is configured to transmit input optical signals to the at least one first press sensing optical fiber and the at least one second press sensing optical fiber, receive output optical signals from the at least one first press sensing optical fiber and the at least one second press sensing optical fiber, and determine press information of the at least one key region according to the output optical signals;

when viewed in a direction perpendicular to a plane formed by the first direction and the second direction, each of the at least one key region includes an intersection of one of the at least one first press sensing optical fiber and one of the at least one second press sensing optical fiber; and

when one of the at least one key region is pressed, the intersection of the first press sensing optical fiber and the second press sensing optical fiber in the key region is deformed.

In an embodiment, the signal processing circuit includes a light source, a photodetector and a processor;

the optical source is configured to transmit the input optical signals to the at least one first press sensing optical fiber and the at least one second press sensing optical fiber:

the photodetector is configured to receive the output optical signals from the at least one first press sensing optical fiber and the at least one second press sensing optical fiber, and to detect data included in the output optical signals; and

the processor is configured to receive the data included in the output optical signals from the photodetector, and to determine the press information of the at least one key region according to the data included in the output optical signals.

In an embodiment, in each of the at least one sub-input region, each of the at least one first press sensing optical fiber intersects each of the at least one press sensing second optical fiber.

In an embodiment, each of the at least one sub-input region includes a plurality of first press sensing optical fibers and a plurality of second press sensing optical fibers, and

in each of the at least one sub-input region, the plurality of first press sensing optical fibers are parallel to each other, and the plurality of second press sensing optical fibers are parallel to each other.

In an embodiment, in each of the at least one sub-input region, a distance between two adjacent first press sensing optical fibers is in a range of 5 mm to 30 mm, and a distance between two adjacent second press sensing optical fibers is in a range of 5 mm to 30 mm.

In an embodiment, each of the at least one first press sensing optical fiber is perpendicular to each of the at least one second press sensing optical fiber.

In an embodiment, the at least one first press sensing optical fiber and the at least one second press sensing optical fiber are all plastic optical fibers.

In an embodiment, the press layer includes a flexible material.

In an embodiment, the press layer has a thickness in a range of 3 mm to 5 mm.

In an embodiment, the input device further includes a protective layer, wherein the protective layer is disposed between the press layer and the at least one first press sensing optical fiber.

In an embodiment, the at least one key region includes a plurality of key regions, and protective layers in the plurality of key regions have a one-piece structure.

In an embodiment, the protective layer includes a flexible material.

In an embodiment, the protective layer has a flexibility higher than a flexibility of the press layer.

In an embodiment, the input device further includes an identification pattern for indicating a meaning of each of the at least one key region.

In an embodiment, the identification pattern is disposed on the press layer and in the corresponding key region.

A second aspect of the present disclosure provides an electronic apparatus including an electronic terminal and any input device according to the embodiments of the first aspect of the present disclosure.

### BRIEF DESCRIPTION OF THE DRAWINGS

FIG. 1 is a schematic diagram illustrating a structure of an input device according to an embodiment of the present disclosure;

FIG. 2 is a schematic cross-sectional view taken along line A-A′ of FIG. 1;

FIG. 3 illustrates a schematic diagram of a curved waveguide of a plastic optical fiber:

FIG. 4 is a schematic diagram illustrating variation of a bending loss of a plastic optical fiber with a curvature radius; and

FIG. 5 is a schematic diagram illustrating a structure and a workflow of a signal processing circuit of an input device according to an embodiment of the present disclosure.

### DETAILED DESCRIPTION

In order to enable those skilled in the art to better understand technical solutions of the present disclosure, the present disclosure will be described in further detail below with reference to the accompanying drawings and exemplary embodiments.

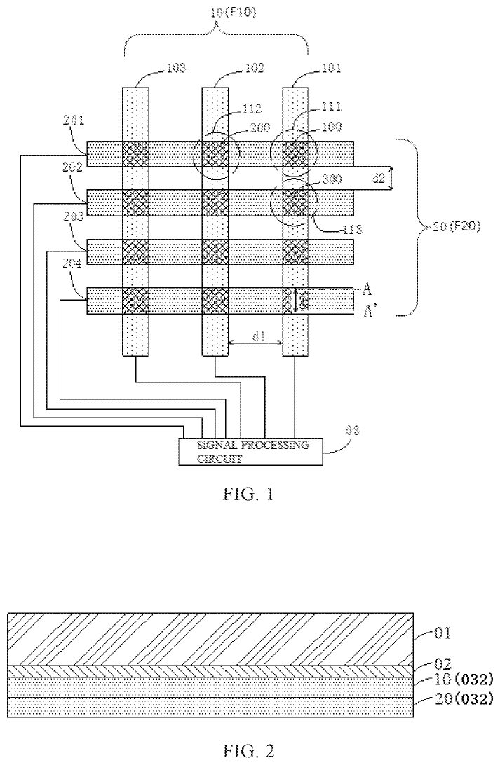

FIG. 1 is a schematic diagram illustrating a structure of an input device according to an embodiment of the present disclosure. FIG. 2 is a schematic cross-sectional view taken along line A-A′ of FIG. 1.

Referring to FIGS. 1 and 2, an input device according to an embodiment of the present disclosure may input information to an electronic terminal, and the input device includes a press layer 01 in at least one key region (or button region), at least one first optical fiber F10, at least one second optical fiber F20, and a signal processing circuit 03.

As shown in FIGS. 1 and 2, each key region (for example, each of key regions 111, 112, and 113 shown in FIG. 1) including the press layer 01 is in an input region of the input device. In other words, the input region of the input device is a region including at least one key region.

As shown in FIGS. 1 and 2, a portion (i.e., a first press sensing optical fiber 10) of each first optical fiber F10 in the input region is on a side of the press layer 01 opposite to a user operation side (which is, for example, an upper side of FIG. 1 or FIG. 2) of the press layer 01, and the portion of the first optical fiber F10 in the input region extends in a first direction (for example, a vertical direction in FIG. 1).

As shown in FIGS. 1 and 2, a portion (i.e., a second press sensing optical fiber 20) of each second optical fiber F20 in the input region is on a side (for example, a lower side), which is away from (or distal to) the press layer 01, of the portion of the first optical fiber F10 in the input region, and the portion of the second optical fiber F20 in the input region extends in a second direction (for example, a horizontal direction in FIG. 1) that intersects the first direction.

It should be noted that the press layer 01 is omitted in FIG. 1 for clarity.

In an embodiment according to the present disclosure, as stated above, the portion of each first optical fiber F10 in the input region may be referred to as a first press sensing optical fiber 10 (for example, one of first press sensing optical fibers 101, 102, and 103 shown in FIG. 1), and the portion of each second optical fiber F20 in the input region may be referred to as a second press sensing optical fiber 20 (for example, one of second press sensing optical fibers 201, 202, 203, and 204 shown FIG. 1), and each of the first press sensing optical fibers 10 and the second press sensing optical fibers 20 may be referred to as a press sensing optical fiber 032, as shown in FIG. 2. In other words, a portion of one first press sensing optical fiber 10 or one second press sensing optical fiber 20 may be referred to as the press sensing optical fiber 032.

In the embodiment shown in FIG. 1, each of the first optical fibers F10 and each of the second optical fibers F20 are directly connected to the signal processing circuit 03. For clarity of explanation, as shown in FIG. 1, the portions of each first optical fiber F10 and each second optical fiber F20 in the input region (that is, each first press sensing optical fiber 10 and each second press sensing optical fiber 20) are shown in the manner of an enlarged view, that is, the portions of each first optical fiber F10 and each second optical fiber F20 in the input region are shown in the manner of having a large width, and portions of each first optical fiber F10 and each second optical fiber F20 outside the input region are shown in the manner of having a small width.

However, in a practical application, the portions of each first optical fiber F10 and each second optical fiber F20 in the input region and portions of each first optical fiber F10 and each second optical fiber F20 outside the input region may have a same width and have a one-piece structure, respectively.

In the embodiment according to the present disclosure, as shown in FIG. 1, when viewed in a direction perpendicular to a plane formed by the first direction and the second direction, each key region includes an intersection (which may be referred to as an intersection point, and may be, for example, one of intersections 100, 200, and 300 shown in FIG. 1) of one of the first press sensing optical fibers 10 and one of the second press sensing optical fibers 20.

In the embodiment according to the present disclosure, when each key region is pressed, portions (including the intersection of the corresponding first and second press sensing optical fibers 10 and 20 in the key region) of the corresponding first and second press sensing optical fibers 10 and 20 in the key region are deformed.

It should be understood that the intersection of one of the first press sensing optical fibers 10 and one of the second press sensing optical fibers 20 refers to a portion where the first press sensing optical fiber 10 and the second press sensing optical fiber 20 overlap each other.

The embodiment shown in FIG. 1 shows that the first press sensing optical fibers 10 include three first press sensing optical fibers 101, 102, and 103, and the second press sensing optical fibers 20 include four second press sensing optical fibers 201, 202, 203, and 204, but the present disclosure is not limited thereto. In some embodiments, the first press sensing optical fibers 10 may include more or less than three first press sensing optical fibers, and the second press sensing optical fibers 20 may include more or less than four second press sensing optical fibers. For example, in an embodiment, the input device may include one first press sensing optical fiber F10 or 10 and one second press sensing optical fiber F20 or 20.

The embodiment shown in FIG. 1 shows that the input device includes 12 key regions respectively including 12 intersections formed by the three first press sensing optical fibers and the four second press sensing optical fibers, but the present disclosure is not limited thereto. In some embodiments, the input device according to the embodiment of the present disclosure may include more or less than 12 key regions respectively including the intersections.

As shown in FIG. 1, the signal processing circuit 03 is coupled to the first and second press sensing optical fibers 10 and 20, and is configured to transmit input optical signals to the first and second press sensing optical fibers 10 and 20, receive output optical signals from the first and second press sensing optical fibers 10 and 20, and determine press information of each of the key regions according to the output optical signals output by the first and second press sensing optical fibers 10 and 20.

In some embodiments, each of the press sensing optical fibers 032 may be a plastic optical fiber (POF). The plastic optical fiber includes polymer and has the advantages of good flexibility, strong magnetic interference resistance, and the like.

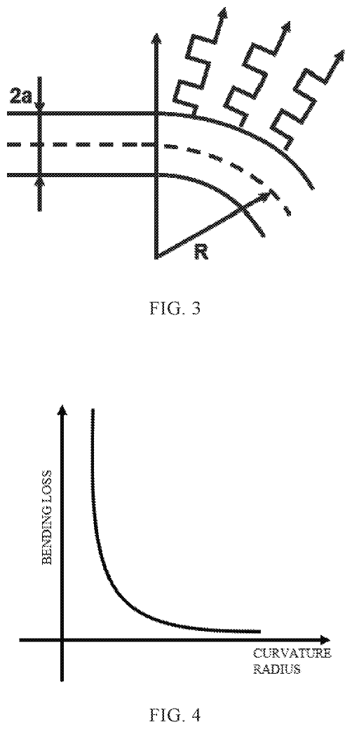

FIG. 3 illustrates a schematic diagram of a curved waveguide of a plastic optical fiber. FIG. 4 is a schematic diagram illustrating variation of a bending loss of a plastic optical fiber with a curvature radius.

Referring to FIG. 3, when the plastic optical fiber is bent by an external force, the optical waveguide of the plastic optical fiber which is not bent becomes a leakage mode or a refraction mode, light transmitted in the plastic optical fiber is lost due to the bending of the plastic optical fiber, and a portion of the light transmitted in the plastic optical fiber leaks outward in a radius direction of a bending portion of the plastic optical fiber.

As shown in FIG. 3, when a curvature radius of the bending portion of the plastic optical fiber is R, a loss coefficient αₑ due to bending may be obtained by the following formula:

$$2 {α}_{e} = \frac{{W}^{2}}{β {a}^{2} ( 1 + W )} \times \frac{{U}^{2}}{{V}^{2}} exp [ 2 W - \frac{2}{3} ( \frac{{W}^{3}}{{β}^{2} {a}^{2}} ) \frac{R}{a} ]$$

where W=\sqrt{β²−k²n₂²} is a radial normalized attenuation constant;

U=\sqrt{k²n₁²−β²} is a radial normalized phase constant:

V is a normalized frequency;

β is an axial propagation constant;

a is a radius of the plastic optical fiber;

k is an extinction coefficient;

n₁ is a refractive index of a core of the plastic optical fiber; and

n₂ is a refractive index of a cladding of the plastic optical fiber.

According to the formula for the loss coefficient, the bending loss of the plastic optical fiber increases sharply as a ratio of the curvature radius R of the pending portion of the plastic optical fiber to the radius a of the plastic optical fiber decreases, and the bending loss of the plastic optical fiber is negligible when the ratio of the curvature radius R of the pending portion of the plastic optical fiber to the radius a of the plastic optical fiber is large. That is, the bending loss of the plastic optical fiber substantially exponentially increases as the curvature radius of the pending portion of the plastic optical fiber decreases, and thus a smaller deformation of the first press sensing optical fiber 10 and the second press sensing optical fiber 20 in each key region may cause a significant change in the intensity of the output optical signal received by the signal processing circuit 03 from the first press sensing optical fiber 10 and the second press sensing optical fiber 20.

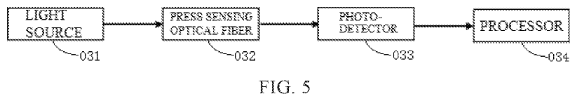

FIG. 5 is a schematic diagram illustrating a structure and a workflow of a signal processing circuit of an input device according to an embodiment of the present disclosure.

In some embodiments, as shown in FIG. 5, the signal processing circuit 03 includes a light source 031, a photodetector 033, and a processor 034. The light source 031 is configured to transmit an input optical signal to each of the press sensing optical fibers 032. The photodetector 033 is configured to receive an output optical signal from each of the press sensing optical fibers 032, and to detect data included in the output optical signal. In some embodiments, the data included in the output optical signal may include information such as a phase, an optical intensity, and the like of the output optical signal. The processor 034 is configured to receive the data included in the output optical signal from the photodetector 033, and to determine the press information of each key region according the received data included in the output optical signal. In some embodiments, the press information of each key region may include information indicating a position of the key region, information indicating a time when the key region is pressed, and the like.

In some embodiments, the processor 034 may determine the information indicating the position of a certain key region, the information indicating the time when the certain key region is pressed, and the like, based on a sum of light intensities of the output light signals from the first press sensing optical fiber 10 and the second press sensing optical fiber 20 corresponding to the certain key region (in which the first press sensing optical fiber 10 and the second press sensing optical fiber 20 form an intersection). For example, upon the sum of light intensities of the output light signals from the first press sensing optical fiber 10 and the second press sensing optical fiber 20 corresponding to the certain key region being less than a predetermined threshold is detected at a certain time, the processor 034 determines that the user has input a character corresponding to the certain key region and records the certain time as the time when the certain key region is pressed. The predetermined threshold may be the sum of light intensities of the output light signals from the first press sensing optical fiber 10 and the second press sensing optical fiber 20 corresponding to the certain key region when the certain key region is not pressed, and may be determined in advance through experiments.

In this case, as shown in FIG. 5, the light source 031 transmits the input light signal to each of the press sensing optical fibers 032. When the user presses a key region of the input device from the user operation side (for example, the upper side in FIG. 1 or 2), the press of the user causes the press sensing optical fibers 032 in the key region to be deformed. Accordingly, the photodetector 033 detects that the data included in the output optical signals output by the press sensing optical fibers 032 changes due to the deformation of the press sensing optical fibers 032, and transmits the changed data included in the output optical signals to the processor 034, and the processor 034 determines the press information of the key region (for example, the information indicating the position of the key region, the information indicating the time when the key region is pressed, and the like) according to the received changed data included in the output optical signals.

As described above, a small deformation of each of the plastic optical fibers may cause a large bending loss. Accordingly, the user can input information to the electronic terminal by pressing each key region with a slight pressure, and the sensitivity of the input device (for example, a keyboard) according to the embodiment of the present disclosure may be high.

Since the press information of each key region is sensed by using the plastic optical fibers, poor contact will not occur in the input device, and the input device has strong anti-electromagnetic interference capability and has no noise.

The embodiments of the present disclosure illustrate that each of the press sensing optical fibers is a plastic optical fiber, but the present disclosure is not limited thereto. In some embodiments, each of the press sensing optical fiber may be an optical fiber such as a glass optical fiber.

In some embodiments, the press layer 01 may include a flexible material to ensure that a slight pressure applied on the press layer 01 can deform the press sensing optical fibers 032 and increase the sensitivity of each key region. For example, the flexible material may include plastic, polyimide, and/or the like.

In some embodiments, in order to further increase the sensitivity of each key region, the thickness of the press layer 01 may be small, and thus the thickness (for example, a dimension in the vertical direction of FIG. 2) of the input device (for example, a keyboard) according to embodiments of the present disclosure may be small. In some embodiments, the thickness of the press layer 01 may be in the range of 3 mm to 5 mm.

The press layer 01 and the press sensing optical fibers 032 according to the embodiments of the present disclosure may be easily manufactured, and thus the manufacturing process of the input device according to the embodiments of the present disclosure is relatively simple and low in cost.

In some embodiments, the input region of the input device according to the embodiments of the present disclosure may include at least one sub-input region, each sub-input region includes at least one first press sensing optical fiber 10, at least one second press sensing optical fiber 20, and at least one key region (the press layer 01 may be on a side of each key region proximal to the user). In some embodiments, each sub-input region includes a plurality of first press sensing optical fibers 10, a plurality of second press sensing optical fibers 20. In this case, each first press sensing optical fiber 10 intersects at least one second press sensing optical fiber 20, and each second press sensing optical fiber 20 intersects at least one first press sensing optical fiber 10. Each key region includes an intersection of one first press sensing optical fiber 10 and one second press sensing optical fiber 20.

For example, the structure of each key region may be as shown in FIG. 2. For example, the input region may be the entire region defined by the first press sensing optical fibers 10 and the second press sensing optical fibers 20 shown in FIG. 1.

In some embodiments, the input region of the input device according to the embodiments of the present disclosure may include a plurality of sub-input regions, and each sub-input region may include a plurality of key regions. For example, the input device according to the embodiments of the present disclosure may be a keyboard for inputting information to a personal computer (PC), the keyboard may include a first sub-input region and a second sub-input region, the first sub-input region may be the main keyboard region of the keyboard including a plurality of keys corresponding to a plurality of key regions such as alphabetic keys (for example, the key “A”, the key “B”, and the like), symbolic keys (for example, the key “ENTER”, the key “SHIFT”, and the like), and the like, and the second sub-input region may be the keypad region on the right side of the keyboard that includes a plurality of keys, corresponding to a plurality of key regions such as numeric keys (for example, the key “1”, the key “0”, and the like), mathematical symbol keys (for example, the key “+”, the key “*”, and the like), and the like.

Since each key region includes an intersection of one first press sensing optical fiber 10 and one second press sensing optical fiber 20, upon the deformations of the one first press sensing optical fiber 10 and the one second press sensing optical fiber 20 corresponding to the key region are detected at the same time, it may be determined that the key region is pressed. For example, as shown in FIG. 1, upon it is detected at the same time that the press sensing optical fiber 101 of the plurality of first press sensing optical fibers 10 and the press sensing optical fiber 201 of the plurality of second press sensing optical fibers 20 are deformed, it may be determined that the key region 111 is pressed.

It will be understood that since an optical fiber is relatively thin, the area occupied by the intersection of the first press sensing optical fiber 10 and the second press sensing optical fiber 20 is relatively small. Thus, the intersection of the first and second press sensing optical fibers 10 and 20 may occupy only a portion of the corresponding key region (for example, each intersection may be located at the center of the corresponding key region). For example, as shown in FIG. 1, the area of the first intersection 100 may be less than the area of the corresponding first key region 111, the area of the second intersection 200 may be less than the area of the corresponding second key region 112, and the area of the third intersection 300 may be less than the area of the corresponding third key region 113.

In some embodiments, each first press sensing optical fiber 10 intersects all second press sensing optical fibers 20 in the input region or each sub-input region. Therefore, the number of the key regions provided in the input region or the sub-input region may be equal to the number of the first press sensing optical fibers 10 multiplied by the number of the second press sensing optical fibers 20.

In some embodiments, the plurality of first press sensing optical fibers 10 are parallel to each other and the plurality of second press sensing optical fibers 20 are parallel to each other, so as to reduce the mutual influence between the optical fibers, simplify the layout of the optical fibers, and reduce the complexity of manufacturing the input device.

In some embodiments, a distance between two adjacent first press sensing optical fibers 10 is in a range of 5 mm to 30 mm, and a distance between two adjacent second press sensing optical fibers 20 is in a range of 5 mm to 30 mm.

For example, as shown in FIG. 1, the distance d1 between the press sensing optical fiber 101 and the press sensing optical fiber 102 of the plurality of first press sensing optical fibers 10 is equal to 15 mm, and the distance d2 between the press sensing optical fiber 201 and the press sensing optical fiber 202 of the plurality of second press sensing optical fibers 20 is equal to 10 mm.

In some embodiments, each of the first press sensing optical fibers 10 is perpendicular to each of the second press sensing optical fibers 20.

In some embodiments, as shown in FIG. 2, a protective layer 02 for protecting the press sensing optical fibers 032 may be disposed between the press layer 01 and the press sensing optical fibers 032.

In some embodiments, the protective layer 02 may include a flexible material. In some embodiments, the protective layer 02 may be more flexible than the press layer 01 (that is, the flexibility of protective layer 02 is higher than the flexibility of press layer 01) such that the pressure applied to each key region effectively causes the corresponding press sensing optical fibers 032 to be bent.

In some embodiments, the protective layers 02 in respective key regions are integrally formed (i.e., are formed to have a one-piece structure). Accordingly, the press sensing optical fibers 032 may be fully protected, and the protective layer 02 may be conveniently manufactured.

In some embodiments, the input device according to the embodiments of the present disclosure may further include an identification pattern for indicating a meaning of a corresponding key region. For example, the identification pattern may indicate that the corresponding key region represents the key “A”. In some embodiments, the identification pattern may be disposed on the press layer 01 and in the corresponding key region. For example, the identification pattern may be disposed on a side of the press layer 01 away from (or distal to) the press sensing optical fibers 032. In some embodiments, an identification pattern may be provided on the press layer 01 for each key region. In some embodiments, the press layer 01 may be transparent, and the identification pattern may be disposed on the protective layer 02 and in the corresponding key region. For example, the identification pattern is a pattern having a white character on a black background.

The input device according to the embodiments of the present disclosure may include, but are not limited to: a conventional physical keyboard, a notebook computer keyboard, a detachable keyboard, a touch keyboard, and the like. The input device according to the embodiments of the present disclosure may also be any device for inputting information to the electronic terminal in the form of pressing keys, such as a keyboard of a calculator, a remote controller of a home appliance, a control button of a home appliance, and the like.

The electronic terminal may be a personal digital assistant (PDA), a desktop computer, a tablet computer, a television, a mobile phone, and the like.

An embodiment of the present disclosure provides an electronic apparatus including the electronic terminal and the input device described above.

The terms “first”, “second”, and the like, are used herein solely for the purpose of distinguishing similar items or items that are substantially the same in function and effect from each other, and not for the purpose of limiting the number, order, or importance of the similar items or items that are substantially the same in function and effect. Herein, the terms “comprising”, “including”, and the like, mean that the element before each of the terms can include other elements in addition to the element(s) after the term.

It will be understood that the above embodiments are merely exemplary embodiments for the purpose of illustrating the principle of the present disclosure, and the present disclosure is not limited thereto. It will be apparent to those skilled in the art that various changes and modifications may be made therein without departing from the spirit and scope of the present disclosure, and these changes and modifications also fall into the protection scope of the present disclosure.

What is claimed is:

1. An input device for inputting information to an electronic terminal, comprising an input region and a signal processing circuit,
wherein the input region comprises at least one sub-input region, each of the at least one sub-input region comprises at least one first press sensing optical fiber, at least one second press sensing optical fiber and at least one key region;
each of the at least one key region comprises a press layer;
the at least one first press sensing optical fiber is on a side of the press layer opposite to a user operation side of the press layer and extends in a first direction;
the at least one second press sensing optical fiber is on a side of the at least one first press sensing optical fiber distal to the press layer and extends in a second direction intersecting the first direction;
the signal processing circuit is coupled to the at least one first press sensing optical fiber and the at least one second press sensing optical fiber, and is configured to transmit input optical signals to the at least one first press sensing optical fiber and the at least one second press sensing optical fiber, receive output optical signals from the at least one first press sensing optical fiber and the at least one second press sensing optical fiber, and determine press information of the at least one key region according to the output optical signals;
when viewed in a direction perpendicular to a plane formed by the first direction and the second direction, each of the at least one key region comprises an intersection of one of the at least one first press sensing optical fiber and one of the at least one second press sensing optical fiber; and
when one of the at least one key region is pressed, the intersection of the first press sensing optical fiber and the second press sensing optical fiber in the key region is deformed.

2. The input device of claim 1, wherein
the signal processing circuit comprises a light source, a photodetector and a processor;
the optical source is configured to transmit the input optical signals to the at least one first press sensing optical fiber and the at least one second press sensing optical fiber;
the photodetector is configured to receive the output optical signals from the at least one first press sensing optical fiber and the at least one second press sensing optical fiber, and to detect data included in the output optical signals; and
the processor is configured to receive the data included in the output optical signals from the photodetector, and to determine the press information of the at least one key region according to the data included in the output optical signals.

3. The input device of claim 1, wherein
in each of the at least one sub-input region, each of the at least one first press sensing optical fiber intersects each of the at least one press sensing second optical fiber.

4. The input device of claim 3, wherein
each of the at least one sub-input region comprises a plurality of first press sensing optical fibers and a plurality of second press sensing optical fibers, and
in each of the at least one sub-input region, the plurality of first press sensing optical fibers are parallel to each other, and the plurality of second press sensing optical fibers are parallel to each other.

5. The input device of claim 4, wherein in each of the at least one sub-input region, a distance between two adjacent first press sensing optical fibers is in a range of 5 mm to 30 mm, and a distance between two adjacent second press sensing optical fibers is in a range of 5 mm to 30 mm.

6. The input device of claim 1, wherein each of the at least one first press sensing optical fiber is perpendicular to each of the at least one second press sensing optical fiber.

7. The input device of claim 1, wherein the at least one first press sensing optical fiber and the at least one second press sensing optical fiber are all plastic optical fibers.

8. The input device of claim 1, wherein the press layer comprises a flexible material.

9. The input device of claim 8, wherein the press layer has a thickness in a range of 3 mm to 5 mm.

10. The input device of claim 1, further comprising a protective layer, wherein the protective layer is disposed between the press layer and the at least one first press sensing optical fiber.

11. The input device of claim 10, wherein the at least one key region comprises a plurality of key regions, and protective layers in the plurality of key regions have a one-piece structure.

12. The input device of claim 10, wherein the protective layer comprises a flexible material.

13. The input device of claim 12, wherein the protective layer has a flexibility higher than a flexibility of the press layer.

14. The input device of claim 1, further comprising an identification pattern for indicating a meaning of each of the at least one key region.

15. The input device of claim 14, wherein the identification pattern is disposed on the press layer and in a corresponding key region.

16. An electronic apparatus, comprising an electronic terminal and the input device of claim 1.
